(19) United States
(12) Patent Application Publication
(10) Pub. No.: US 2024/0047138 A1
(43) Pub. Date: Feb. 8, 2024

(54) HIGH ENTROPY, HIGH DIELECTRIC SWING HETEROGENEOUS MATERIALS

(71) Applicant: Raytheon Company, Waltham, MA (US)

(72) Inventors: Kalin Spariosu, Thousand Oaks, CA (US); Connie Shen, Gardena, CA (US)

(21) Appl. No.: 18/366,438

(22) Filed: Aug. 7, 2023

Related U.S. Application Data
(60) Provisional application No. 63/396,081, filed on Aug. 8, 2022.

(51) Int. Cl. H01G 4/14

(52) U.S. Cl. CPC H01G 4/14

(57) ABSTRACT

Devices, systems, and methods for micro-scale capacitance excursions in a porous medium are provided. A method can include forming pores in polymer or a metal oxide powder resulting in a porous film, injecting conductive nanoparticles into the porous film resulting in a conductive porous film, and curing the conductive porous film resulting in the high entropy, high dielectric swing heterogeneous film.

### CROSS-REFERENCE TO RELATED APPLICATION

This patent application claims the benefit of U.S. Provisional Patent Application No. 63/396,081, filed Aug. 8, 2022, which is incorporated by reference herein in its entirety.

### TECHNICAL FIELD

Embodiments regard devices, systems, and methods for a localized high dielectric constant excursion via metallic particle activation of a polymer material that includes voids.

### BACKGROUND

Some current security features in devices use micro capacitor arrays. These arrays do not have sufficiently high entropy or bit density for many applications. Some high entropy approaches use solid phase matrix hosts with nano-metallic activation for high bit density, but such materials are limited in sensitivity of capacitance. A micro porous material, such as a carbon nanotube (CNT), has an inherently high base capacitance with low microscale variations.

### BRIEF DESCRIPTION OF THE DRAWINGS

FIG. 1 illustrates, by way of example, a diagram of an embodiment of a high entropy, high dielectric excursion material and a corresponding graph of capacitance across a cross-section of the material.

FIG. 2 illustrates the geometry considered in generating Equation 1 below.

FIG. 3 illustrates, by way of example, a diagram of an embodiment of a material that includes a micro cluster of spheres in a volume segment.

FIG. 4 illustrates, by way of example, a graph of capacitance versus sphere radius for an example material that includes a micro scale cluster of microspheres.

FIG. 5 illustrates, by way of example, a graph of capacitance versus sphere radius for example material that includes a larger average separation between spheres (2.25 microns as opposed to 0.75 microns).

FIG. 6 illustrates, by way of example, a conceptual diagram of a submicron scale material with localized capacitance variation estimates as a function of micro cluster segments and inter-sphere dielectric constant based on localized micro pores.

FIG. 7 illustrates, by way of example, a graph of capacitance versus sphere radius as a function of average dielectric constant between microsphere clusters.

FIG. 8 illustrates, by way of example, a flow diagram of an embodiment of a method for making a high entropy high dielectric swing heterogeneous material.

FIG. 9 illustrates, by way of example, a flow diagram of an embodiment of a method for making a high entropy high dielectric swing heterogeneous material.

FIG. 10 illustrates, by way of example, a flow diagram of an embodiment of a method for making a high entropy high dielectric swing heterogeneous material.

FIG. 11 illustrates, by way of example, a flow diagram of an embodiment of a method for making a high entropy high dielectric swing heterogeneous material.

FIG. 12 illustrates, by way of example, a diagram of an embodiment of a truly authenticatable component.

### DETAILED DESCRIPTION

A rapid increase of autonomous device (e.g., fully autonomous devices) drives a need for self-contained, low size, weight, power, and cost (SWaP-C) self-authentication mechanisms that cannot be observed, bypassed, or falsified. A prior nano feature porous structure has an inherently high base capacitance and a relatively small, localized capacitance variation resulting in poor capacitance sensitivity (e.g., a sensitivity greater than femtoFarads (fF).

Embodiments can generate a highly localized capacitance excursion variation on a micro scale (less than 10 micrometers). The capacitance excursion can still maintain a low average (e.g., bulk) capacitance. These capacitance excursion and low average capacitance can provide a highly sensitive differential capacitance and a high entropy or physically unclonable function (PUF) bit density. Embodiments can achieve the capacitance excursion (localized dielectric difference) using nano-scale (sub-micron) metallic particles and micron sized voids. The metallic particles can be incorporated into a porous, multi-phase polymer host material that includes the micron sized voids.

Embodiments enable a PUF through high dielectric constant randomness (high entropy distribution) of nano-sized particles (e.g., particles with a largest dimension less than one micron) in a low base dielectric constant heterogeneous (e.g., porous) material (e.g., a matrix host).

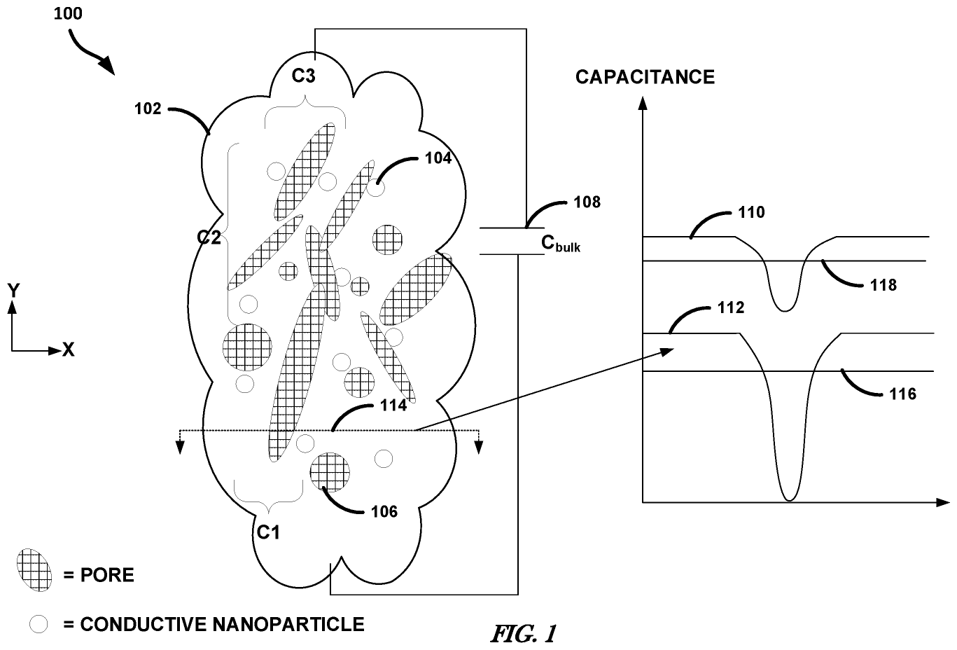

FIG. 1 illustrates, by way of example, a diagram of an embodiment of a high entropy, high dielectric excursion material 100 and a corresponding graph of capacitance across a cross-section of the material 100. The material 100 includes a substrate 102 with pores 106 and conductive nanoparticles 104 integrally formed therewith. The substrate 102 can include a polymer, resin, prepreg, metal, ceramic, a combination thereof, or the like. The substrate 102 forms a lattice into which the nanoparticles 104 and pores 106 are integrated. A distance between the nanoparticles 104 and dielectric constant of the pores and substrate 102 between nanoparticles defines a capacitance. Different distances or dielectric constants thus create different capacitances across different portions of the material 100. C1, C2, and C3 represent areas of the material 100 with different capacitances.

A capacitor 108 represents an average capacitance across an entire length (y-direction) of the material 100. The average capacitance of the material 100 is represented by line 116 on the graph in FIG. 1.

The pores 106 can be voids (gaps with air or another gas therein) between solid portions of the substrate 102. The pores can have low dielectric constants, close to ˜>1 equivalent to “air”. The dielectric constant is the ratio of the permittivity of a substance to the permittivity of free space. The pores 106 can include a length (y), width (x), height (z), or a combination thereof that is less than a micrometer. Pores of such a size are considered sub-micron, or nanopores.

The conductive nanoparticles 104 can include a metal, quantum dot (QD), or the like that form “plates” of capacitors, or otherwise affect the capacitance across an area of the material 100. The conductive nanoparticles 104 can include a length (y), width (x), height (z), or a combination thereof that can vary in size from 10s of nanometers to about or less than 1 micrometer.

The combination of nanoparticles 104 and pores 106 in the substrate 102 causes the material 100 to have a lower average capacitance 116 than prior thin film materials. An average capacitance 114 of the prior material is shown in the graph. Also, the combination of the nanoparticles 104 and pores 106 in the substrate 102 causes the material 100 to have a higher capacitance excursion (on average) than the prior material. The capacitance excursion is the difference between the highest capacitance and the lowest capacitance measured across the cross-section of the material. The larger change in capacitance means that the material has a higher entropy than the prior materials. Higher entropy means that it is more difficult to re-create or imitate the material. Thus, the material 100 can provide a more secure physically unclonable function (PUF) than a material with lower entropy.

The graph on FIG. 1 shows an average capacitance 118 for a prior material that is higher than the average capacitance 116 of the material 102. The average capacitance 116 of the material 100 can be on the order of femtoFarads (fF)? While the average capacitance 118 of the prior material can be on the order of several (few to 10s of fF) with targeted micro scale dimensions of about 1 to about 5 microns. The excursion (size of the dip in capacitance 110 across a cross-section) of the prior material is smaller than the excursion (size of the dip in capacitance 112 across the cross-section 114) of the material 100. The excursion for the material 100 is greater than femtoFarads, while the excursion for the prior material is on the order of femtoFarads.

Based on a rigorous treatise of capacitance between conducting spheres performed by Banarje et al. titled “Approximate Capacitance Expressions for Two Equal Sized Conducting Spheres”, in the Department of Physics at Rhodes College, the capacitance between equal sized metallic spheres in a representative instantiation of micropores present or absent between the micro spheres is given by Equation 1:

$${C}_{m} = x * \frac{4 * π * ε * {ε}_{0} * R}{1 + {x}^{2}} * [ 1 + 0.5 * ln [ \frac{1 + {x}^{4}}{{( 1 - {x}^{2} )}^{2}} ] + k * {( ( 2 * {x}^{2} - {x}^{4} ) / ( 2 - 2 * {x}^{2} - {x}^{4} ) )}^{2.15} ] \qquad Equation 1$$

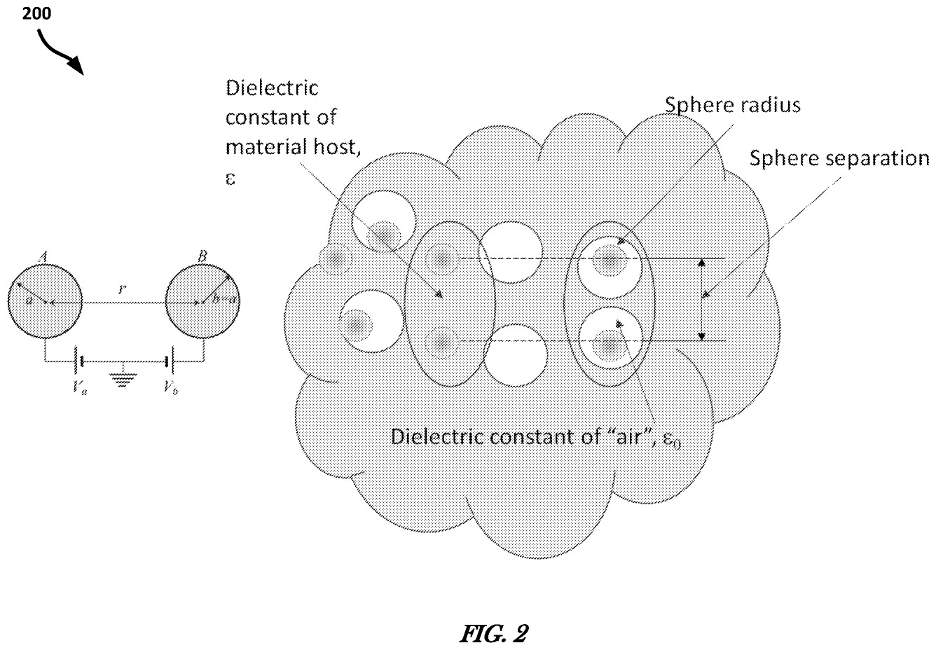

FIG. 2 illustrates the situated considered in generating Equation 1. This shows the notional geometry of capacitance between two equal sized metallic spheres in a representative instantiation of micropores present or absent between the micro spheres.

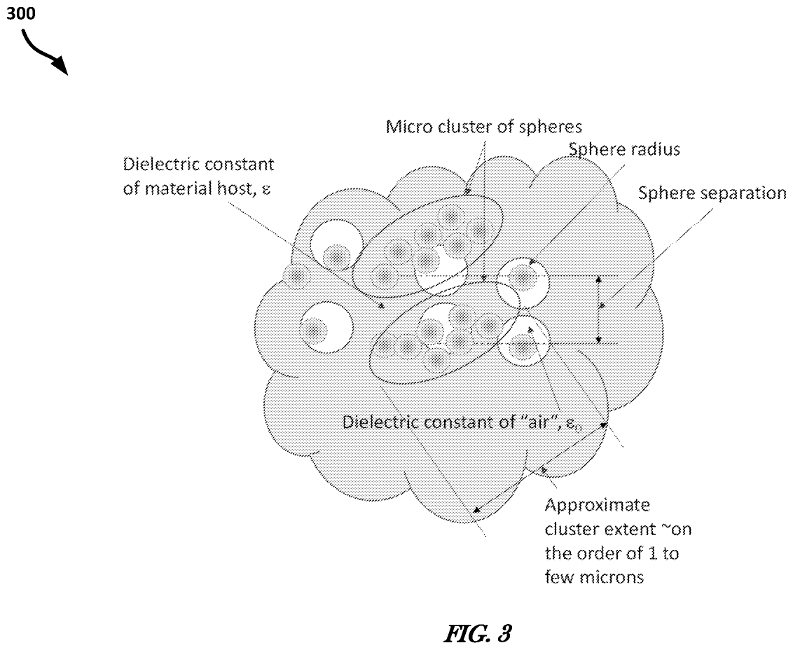

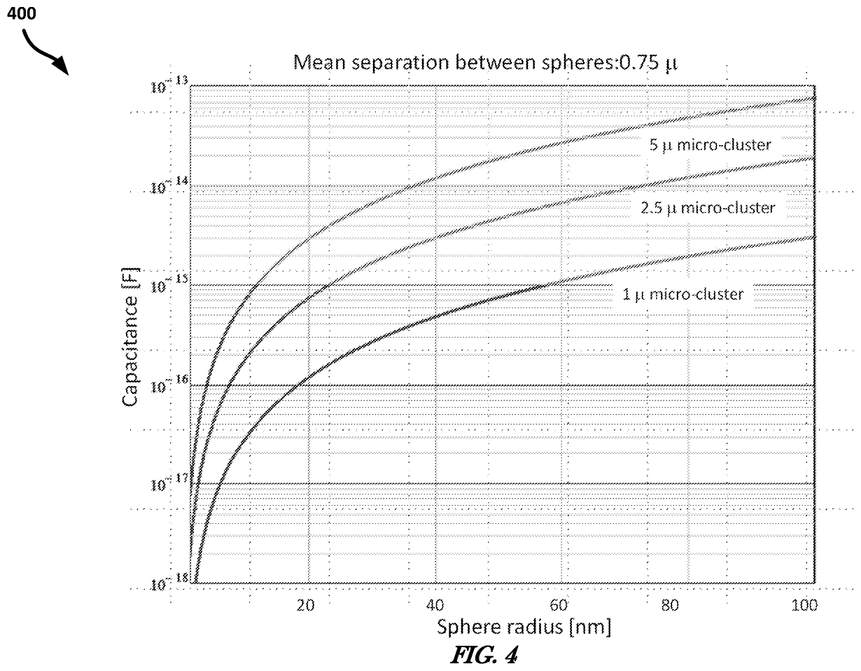

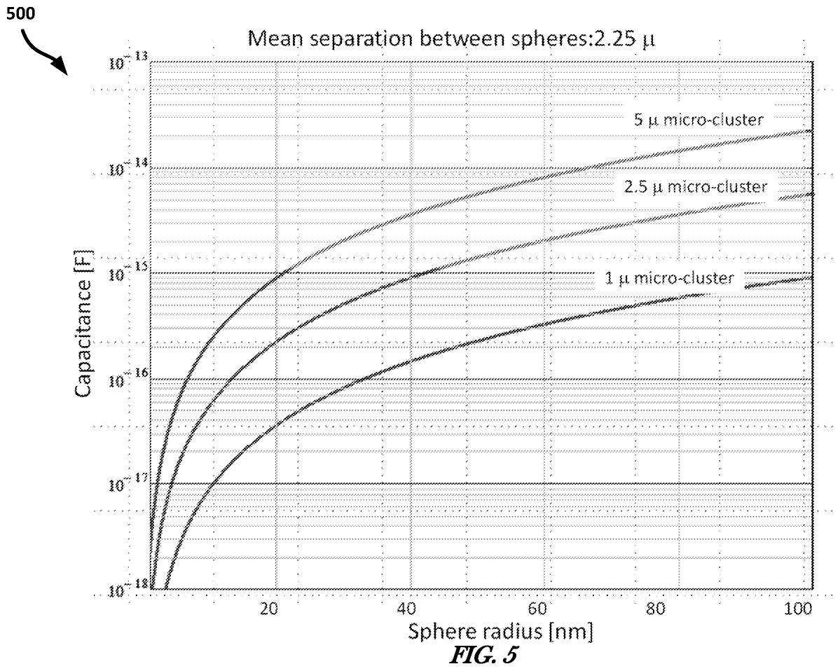

FIG. 3 illustrates, by way of example, a diagram of an embodiment of a material 300 that includes a micro cluster of spheres in a volume segment. FIG. 4 illustrates, by way of example, a graph 400 of capacitance versus sphere radius for an example material that includes a micro scale cluster of microspheres. The average separation between spheres in FIG. 4 is about 0.75 microns. A darker region of the graph shows where capacitance values of about 1 fF to several 10s of fF can be realized. In this range, detection sensor circuitry is capable of reliable detection. There is a variety of micro sphere diameters in this example ranging from less than 20 nm to about 100 nm in diameter. Another example where the mean separation between the micro-sphere clusters is greater, (e.g., greater than 2 microns) is shown in FIG. 5.

FIG. 5 illustrates, by way of example, a graph 500 of capacitance versus sphere radius for example material that includes a larger average separation between spheres (2.25 microns as opposed to 0.75 microns). For the example of FIG. 5, target microsphere diameters of usable range are greater than about 50 nm. The microsphere incorporated porous medium is a parameter that can be optimized based on various host polymers.

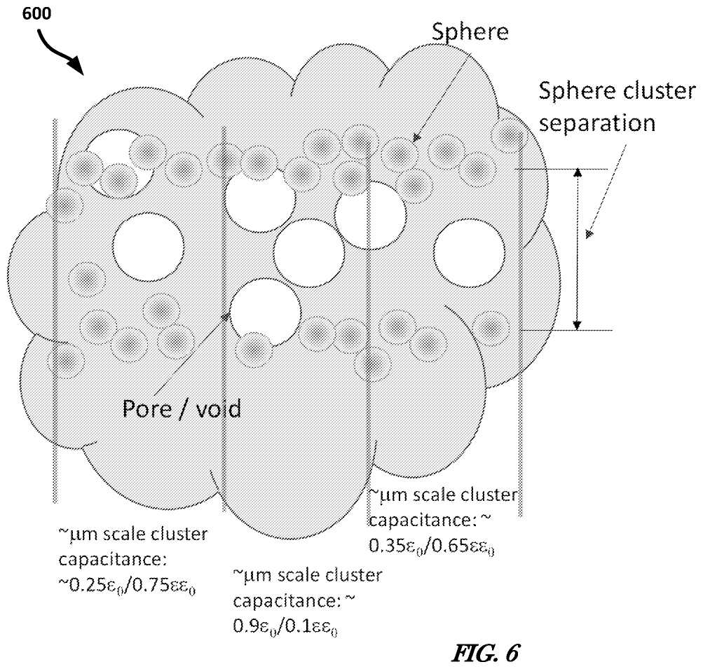

The micro-scale localized capacitance (enhanced) excursion estimates is based on a representative instantiation of expected random localization of micro-pores of a representative a microsphere incorporated medium as a function of dimensional extent as shown in FIG. 6.

FIG. 6 illustrates, by way of example, a conceptual diagram of a submicron scale material 600 with localized capacitance variation estimates as a function of micro cluster segments and inter-sphere dielectric constant based on localized micro pores. The excursion of capacitance can be estimated as a function of micron scale dimension extents via a ratio of micropores to host/base materials in between the microsphere cluster segments. For a notional material dielectric constant of 20, these excursions can vary up to about 20 times as compared with a similar host without micropores present.

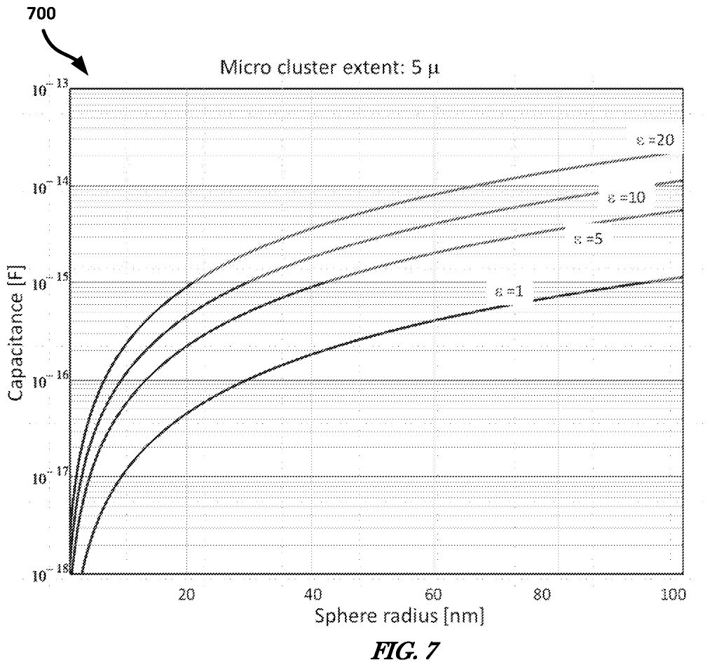

FIG. 7 illustrates, by way of example, a graph of capacitance versus sphere radius as a function of average dielectric constant between microsphere clusters. Capacitance excursions as high as 20× can be realized as compared to a non-porous host medium case.

The following examples are non-limiting representative embodiments/processes of synthesizing nano crystals incorporated porous material/media. These are non-limiting example methods of generating a micro/nano sphere incorporated porous host medium.

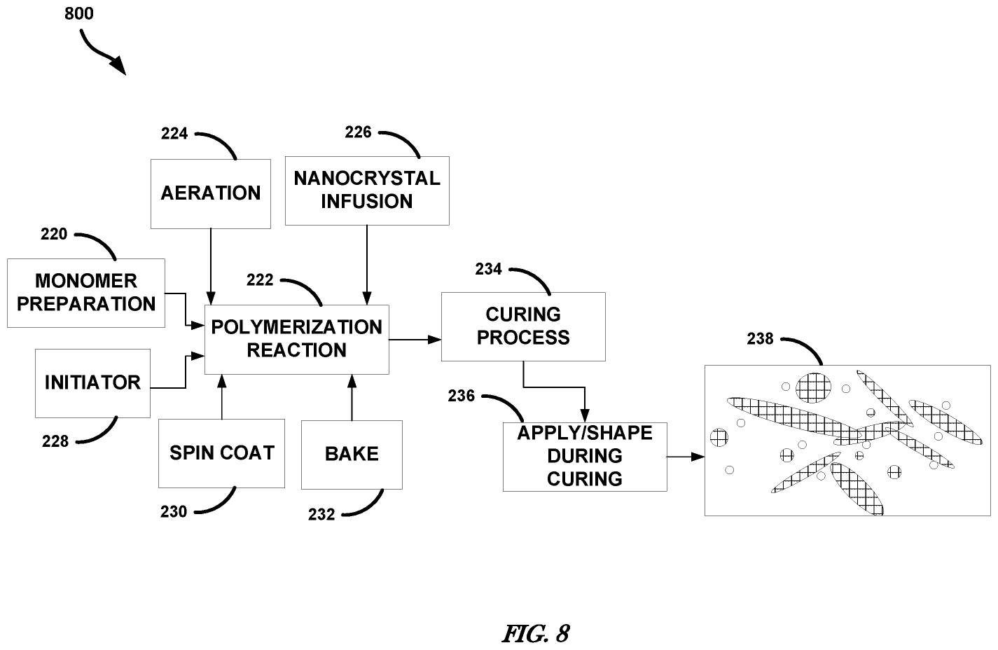

FIG. 8 illustrates, by way of example, a flow diagram of an embodiment of a method 800 for making a high entropy high dielectric swing heterogeneous material 238. The material 238 is an example of the material 100. A polymerization reaction 222 can form a malleable high entropy high dielectric swing heterogeneous material. The polymerization reaction 222 can begin with monomer preparation 220. A monomer is a molecule that can be bonded to other same molecules to form a polymer. Example monomers include glucose, vinyl, amino acids, and ethylene, among others. Monomer preparation 220 can include specific accommodation of appropriate solvent commensurate with intended nanocrystal addition in further process preparation steps.

An initiator 228 can be added to the prepared monomer. The initiator can react with the monomer to form an intermediate compound capable of linking successively with other monomers to form a polymer. Example initiators includes peroxides, aliphatic azo compounds, and methyl methacrylate, among others.

The monomer and initiator can be spun into a film using a spin coating 230. The spin coating 230 applies a uniform film onto a solid surface by using centrifugal force. In a typical spin coating, a circular surface is rotated rapidly to produce a uniform film of about 1-10 um thick. Introducing pores or conductive nanoparticles into a film that thin is difficult.

The uniform film can be exposed to aeration 224 or mechanical perturbation (e.g., shaking with a motor, on a plate, or the like). The aeration 224 is a process by which air (other gases can be used as well) is circulated through, mixed with or dissolved in a liquid or other substance. The circulated gas forms pores in the film. The pores are less than one micrometer in at least one dimension and are therefore nanopores. The aeration also brings the liquid monomer, initiator, and infused nanocrystals into close contact so they can interact and bond.

A nanocrystal infusion 226 introduces nanoparticles into the polymerization reaction. Example nanocrystals include quantum dots (QDs), silicon, ferrous materials, cadmium telluride, and semiconductors, among others. The nanoparticles provided by the nanocrystal infusion 226 can have a high dielectric constant (e.g., dielectric constant greater than 6). The pores formed by aeration can have a low dielectric constant (e.g., a dielectric constant less than 3). Thus, when the material 238 transitions from a pore, nanoparticle, or the substrate to another of the pore, nanoparticle, or the substrate the capacitance of the material changes significantly. This results in a larger capacitance excursion.

The polymerization reaction 222 can include a bake 232 operation. The bake 232 operation can increase a temperature of the polymer being formed so as to energize particles of the polymerization reaction and reduce time it takes to form the resultant polymer. The bake 232 operation can be performed using an oven, a heat lamp, air dryer, or the like. The bake 232 operation can be a nitrogen purged atmosphere baking.

A curing process 234 can be performed to make the material 238 a solid. The curing process 234 can include exposing the polymer from the polymerization reaction to a higher temperature for a specified period of time. Before the polymer is fully cured, it can be malleable. In its malleable state, the polymer can be applied to a component, shaped, or otherwise altered. Note the polymer 238 can be applied to a component after forming is complete (e.g., after curing 234).

When applied to a component, the material 238 can be electrically tested to verify that the component it is attached to is authentic, trustworthy, or the like. The material 238, because it has high entropy and a unique capacitance signature per cross-section can provide an authenticating signature for the component to which the material 238 is attached or associated with.

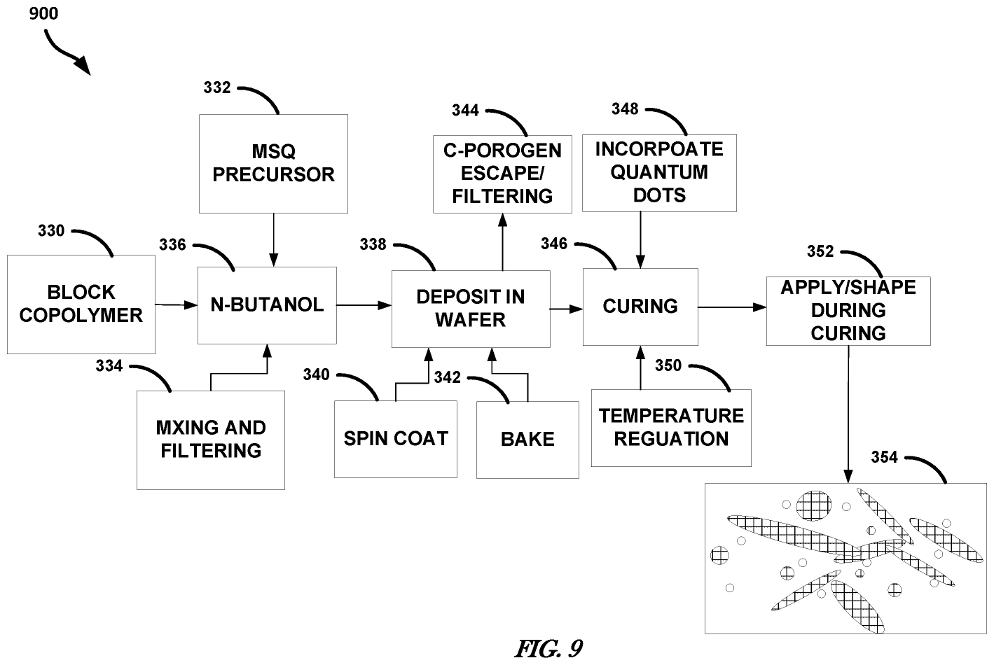

FIG. 9 illustrates, by way of example, but not limited to, a flow diagram of an embodiment of a method 900 for making a high entropy high dielectric swing heterogeneous material 354. The material 354 is another example of the material 100. The method 300 includes a chemical intermediate, N-butanol 336, that is mixed with a methylsilsesquioxane (MSQ) precursor 332 and a block copolymer 330. The MSQ precursor 332 can combine with the block copolymer 330 to form a porous material.

The block copolymer 330 is a polymer comprising molecules in which there is a linear arrangement of blocks. A block is defined as a portion of a polymer molecule in which a monomer has a feature absent from the adjacent portions. Examples of the block copolymer 330 include polystyrene-b-poly(methyl methacrylate) or PS-b-PMMA (where b=block), nitrile, ethylene-vinyl acetate

The N-butanol 336, MSQ precursor 332, and block copolymer 330 (jointly called the “N-butanol solution”) can be combined through a mix, stir, filter, or similar operation 334. The operation 334 can provide kinetic energy to the N-butanol solution resulting in a liquid solution.

The liquid solution can be deposited on a wafer 338. The wafer can include a substrate that does not react with the liquid solution or does react with the liquid solution, depending on the application. The liquid solution can be spin coated 340 on the wafer. The spin coating 340 is similar to the spin coating 230. Spin coating can be performed be performed at between 2000-3000 rotations per minute (rpm), at room temperature, or a combination thereof.

A porogen (a pore generating material) can escape or be filtered out of the liquid solution at operation 344. The porogen can be introduced into the N-butanol solution. The porogen can help expedite the chemical bonding in the N-butanol solution.

The wafer with the film from spin coating 340 the N-butanol solution can be baked 342 (e.g., after or concurrent with the porogen removal at operation 344. Baking 342 is similar to the baking 232. The baking can be performed at over 100 degrees Celsius, in ambient air, in nitrogen purged air, or a combination thereof.

A nanoporous material that is formed on the wafer can be cured by a curing process 346. The curing can include baking in a nitrogen purged oven. While the nanoporous material is curing, QDs or other nanocrystals can be incorporated into the nanoporous material at operation 348. The operation 348 can include surface diffusion of the QDs.

The curing process 346 can include temperature regulation 350. The temperature regulation 350 can include increasing the temperature at a uniform rate (e.g., specified number of degrees Celsius per unit time) up to a specified temperature and then cooling the material. The specified number of degrees Celsius can be about 1.5 and the specified temperature can be about 500. The result of the curing process is a nanocrystal infused, activated porous polymer matrix represented as the material 354. Similar to the material 238, the material 354 can be, before the polymer is fully cured, malleable. In its malleable state, the polymer can be applied to a component, shaped, or otherwise altered. Note the polymer 354 can be applied to a component after forming is complete (e.g., after curing 346).

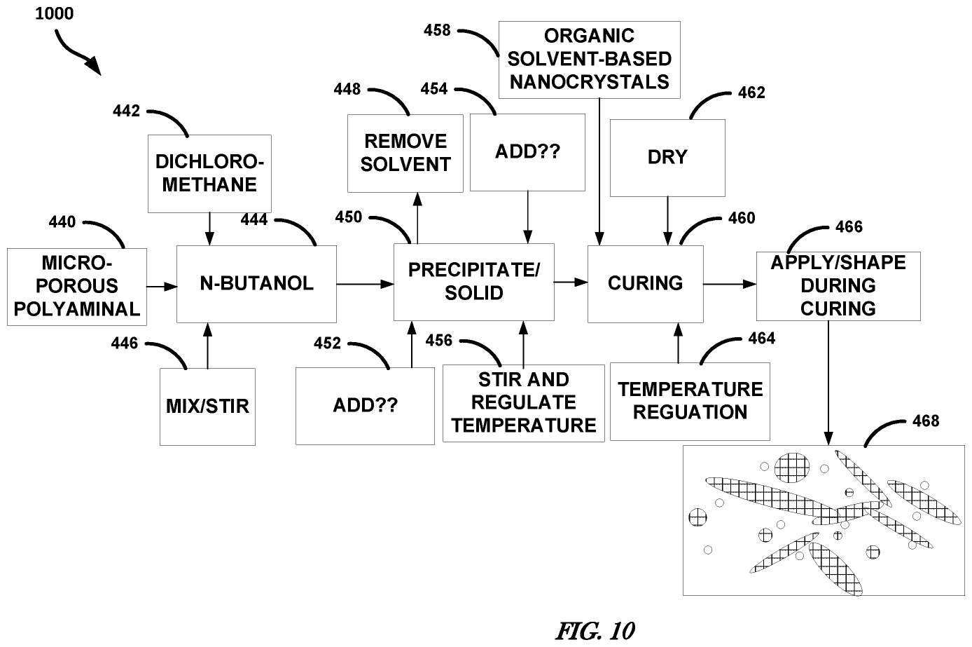

FIG. 10 illustrates, by way of example, but not limited to, a flow diagram of an embodiment of a method 1000 for making a high entropy high dielectric swing heterogeneous material 468. The material 468 is another example of the material 100. The method 1000, similar to the method 900, includes forming an N-butanol solution with the N-butanol solution of FIG. 10 being formed by a combination of micro-porous polyamine 440, dichloromethane 442, and N-butanol 444. The N-butanol solution can be mixed or stirred 446 to form a porous N-butanol solution that is a precipitate or solid 450. Mixing or stirring 446 can be performed for a wide range of time, such as to help ensure a near complete mixing of the N-butanol solution. Common mixing or stirring times range from one hour or less, up to 12 or more hours.

A micro-porous polyamine is a molecular structure with micropores with dimension in about the single nanometer range. Example micro-porous polyamines include 1,3,5,7-tetraphenyladamantane, 1,3,5,7-tetrakis(4 iodophenyl)adamantine, and 1,3,5,7-tetrakis(4-methoxyphenyl) adamantine, among others.

The precipitate or solid 450 formed by the N-butanol solution can be processed, such as by removing the solvent 448. The solvent can be removed by reducing pressure and allowing for evaporation. A cesium carbonate, DMSO, or 1, 2 dibromotetrafluoroethane can be added to the precipitate or solid 450 at operation 452.

A granular zinc, acetic acid, and acetonitrile can be added to the precipitate or solid 450 at operation 454. The precipitate or solid 450 along with the particles added at operations 452, 454 can be mixed at a regulated temperature. The temperature for the example particles discussed can be about 80 degrees Celsius.

A cure 460 can be similar to the curing of FIG. 8 or 9. The curing 460 can be performed while the precipitate or solid 450 is dried over an anhydrous material such as sodium sulfate or the like. The curing 460 can include intermittent stirring with temperature regulation 464. The result of curing 460 the precipitate or solid 450 is the high entropy high dielectric swing heterogeneous material 468.

Similar to the materials 238, 354, the material 468 can be, before the polymer is fully cured, malleable. In its malleable state, the polymer can be applied to a component, shaped, or otherwise altered. Note the polymer 468 can be applied to a component after forming is complete (e.g., after curing 460).

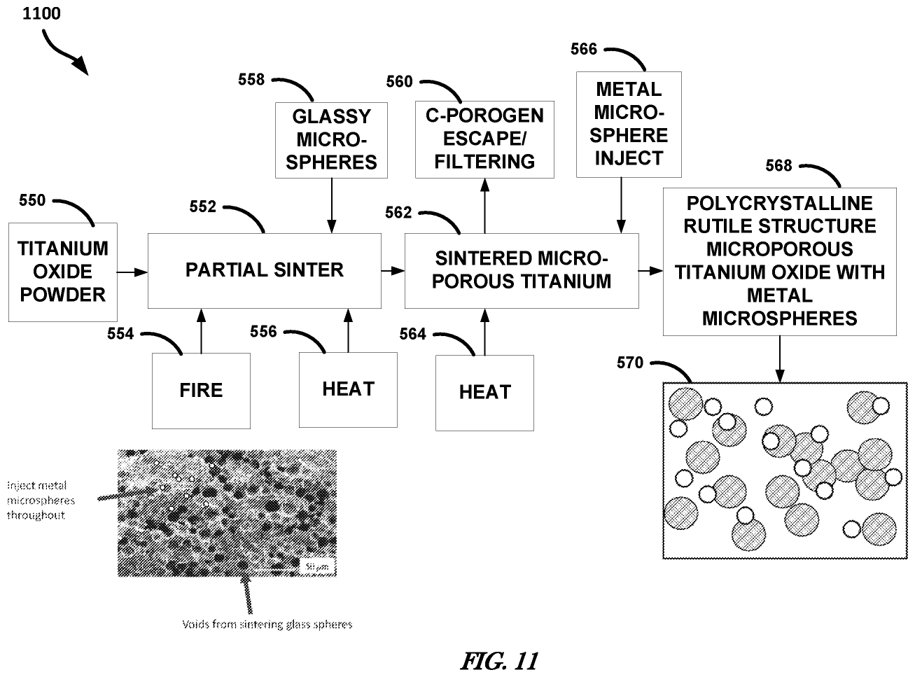

FIG. 11 illustrates, by way of example, but not limited to, a flow diagram of an embodiment of a method 1000 for making a high entropy high dielectric swing heterogeneous material 570. The material 570 is another example of the material 100. A titanium oxide powder 550 can be mixed with glass or other material-based microspheres 558 and partially sintered 552 using fire 554 and heat 556. Alternatives to the titanium oxide powder 550 include . Alternatives to the glass microspheres 558 include.

Fire 554 and heat 556 are similar but distinguished in that heat 556 does not include direct flame, while fire 554 includes direct flame. The firing 554 can be performed at high temperatures, such as at about 1150 degrees Celsius to about 1400 degrees Celsius. Heating 556 can be performed at a lower temperature than firing. The heating 556 can be performed at about 400 degrees Celsius to about six hundred forty degrees Celsius. Sintering is a process of turning a powder into a coalesced solid. Sintering can include heat, compression (without liquification), or a combination thereof. A result of sintering is a sintered micro-porous titanium oxide powder 562.

The spheres 558 can be removed at operation 560 leaving pores where the spheres were once situated. The sintered microporous titanium oxide powder 562 can be heated 564. The heating 564 can be to a temperature at about which the firing 554 was performed. Concurrent with, or before heating 564, the metal micro spheres can be injected at operation 566. The metal microspheres can include, but not limited to, Au, Cu, Al, Co, Ni, Ag. The combination of the sintered micro-porous titanium and the metal microspheres forms a polycrystalline rutile structure microporous titanium oxide with metal microspheres 568, which is the material 570.

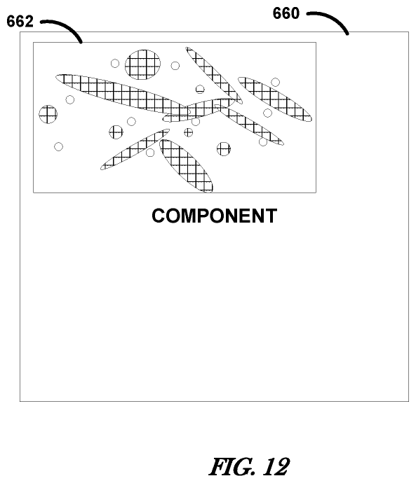

FIG. 12 illustrates, by way of example, a diagram of an embodiment of a truly authenticatable component 660. The component 660 includes a high entropy, high dielectric swing material 662 attached thereto or integrally formed therewith. The material 662 can be used for electrical testing to pass a PUF and authenticate that the component 660 is authentic. The component 660 can include any item to which the material 662 can be attached or into which the material 662 can be integrally formed. The component 660 can include a compute device, a memory device, an electric or electronic component, a piece of paper or other physical document, a mechanical device, a sensor, or a vehicle, among many other items.

Additional Notes and Examples

Example 1 includes a method for making a high entropy, high dielectric swing heterogeneous film, the method comprising forming pores in polymer or a metal oxide powder resulting in a porous film, injecting conductive nanoparticles into the porous film resulting in a conductive porous film, and curing the conductive porous film resulting in the high entropy, high dielectric swing heterogeneous film.

In Example 2, Example 1 further includes, wherein forming pores includes forming the pores in the polymer.

In Example 3, Example 2 further includes aerating and spin coating a monomer and initiator to form the polymer.

In Example 4, Example 3 further includes shaping the high entropy, high dielectric swing heterogeneous film while it is in a malleable state.

In Example 5, at least one of Examples 2-4 further includes mixing a block copolymer and an MSQ precursor with N-butanol resulting in an N-butanol solution.

In Example 6, Example 5 further includes depositing the N-butanol solution on a wafer and spin coating the N-butanol solution on the wafer.

In Example 7, Example 6 further includes, wherein the nanoparticles include quantum dots and injecting the quantum dots includes surface diffusion.

In Example 8, at least one of Examples 2-7 further includes mixing a micro-porous polyamine and dichloromethane with N-butanol resulting in a precipitate or solid N-butanol solution.

In Example 9, Example 8 further includes removing solvent from the N-butanol solution.

In Example 10, Example 9 further includes adding a cesium carbonate, DMSO, or 1, 2 dibromotetrafluoroethane to the precipitate or solid.

In Example 11, Example 10 further includes adding a granular zinc, acetic acid, and acetonitrile to the precipitate or solid.

In Example 12, Example 11 further includes, wherein the nanoparticles are organic, solvent-based nanocrystals.

In Example 13, Example 1 further includes, wherein forming pores includes forming the pores in the metal oxide powder and at least partially sintering the metal oxide powder with glassy micro-spheres in the metal oxide powder.

In Example 14, Example 13 further includes, wherein the nanoparticles are metal microspheres.

Example 15 includes A device comprising a component, and a thin film including a thickness less than 10 micrometers, nanopores, and clusters of conductive nanoparticles situated about the nanopores.

In Example 16, Example 15 further includes, wherein a capacitance of the thin film includes, in any cross-section thereof, a low average capacitance and a high dielectric excursion.

In Example 17, Example 16 further includes, wherein the capacitance of the thin film provides test results for a physically unclonable function (PUF).

In Example 18, at least one of Examples 15-17 further includes, wherein the thin film comprises a polymer with nanocrystals infused therein.

In Example 19, at least one of Examples 15-18 further includes, wherein the thin film comprises a block co-polymer with quantum dots diffused therein.

In Example 20, at least one of Examples 15-19 further includes, wherein the thin film comprises a metal-oxide powder with metal micro-spheres therein.

Although an embodiment has been described with reference to specific example embodiments, it will be evident that various modifications and changes may be made to these embodiments without departing from the broader spirit and scope of the invention. Accordingly, the specification and drawings are to be regarded in an illustrative rather than a restrictive sense. The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

What is claimed is:

1. A method for making a high entropy, high dielectric swing heterogeneous film, the method comprising:
forming pores in polymer or a metal oxide powder resulting in a porous film;
injecting conductive nanoparticles into the porous film resulting in a conductive porous film; and
curing the conductive porous film resulting in the high entropy, high dielectric swing heterogeneous film.

2. The method of claim 1, wherein forming pores includes forming the pores in the polymer.

3. The method of claim 2, further comprising aerating and spin coating a monomer and initiator to form the polymer.

4. The method of claim 3, further comprising shaping the high entropy, high dielectric swing heterogeneous film while it is in a malleable state.

5. The method of claim 2, further comprising mixing a block copolymer and an MSQ precursor with N-butanol resulting in an N-butanol solution.

6. The method of claim 5, further comprising depositing the N-butanol solution on a wafer and spin coating the N-butanol solution on the wafer.

7. The method of claim 6, wherein the nanoparticles include quantum dots and injecting the quantum dots includes surface diffusion.

8. The method of claim 2, further comprising mixing a micro-porous polyamine and dichloromethane with N-butanol resulting in a precipitate or solid N-butanol solution.

9. The method of claim 8, further comprising removing solvent from the N-butanol solution.

10. The method of claim 9, further comprising adding a cesium carbonate, DMSO, or 1, 2 dibromotetrafluoroethane to the precipitate or solid.

11. The method of claim 10, further comprising adding a granular zinc, acetic acid, and acetonitrile to the precipitate or solid.

12. The method of claim 11, wherein the nanoparticles are organic, solvent-based nanocrystals.

13. The method of claim 1, wherein forming pores includes forming the pores in the titanium oxide powder and at least partially sintering the titanium oxide powder with glassy micro-spheres in the titanium oxide powder.

14. The method of claim 13, wherein the nanoparticles are metal microspheres.

15. A device comprising:
a component; and
a thin film including a thickness less than 10 micrometers, nanopores, and conductive nanoparticles.

16. The device of claim 15, wherein a capacitance of the thin film includes, in any cross-section thereof, a low average capacitance and a high dielectric excursion.

17. The device of claim 16, wherein the capacitance of the thin film provides test results for a physically unclonable function (PUF).

18. The device of claim 15, wherein the thin film comprises a polymer with nanocrystals infused therein.

19. The device of claim 15, wherein the thin film comprises a block co-polymer with quantum dots diffused therein.

20. The device of claim 15, wherein the thin film comprises a metal-oxide powder with metal micro-spheres therein.
